(19) United States
(12) Patent Application Publication
(10) Pub. No.: US 2025/0157823 A1
(43) Pub. Date: May 15, 2025

(54) DICING METHOD AND RECORDING ELEMENT MANUFACTURING METHOD

(71) Applicant: CANON KABUSHIKI KAISHA, Tokyo (JP)

(72) Inventors: TETSURO YASUKAWA, Chiba (JP); TAKESHI SHIBATA, Kanagawa (JP)

(21) Appl. No.: 19/019,683

(22) Filed: Jan. 14, 2025

Related U.S. Application Data
(63) Continuation of application No. PCT/JP2023/021053, filed on Jun. 6, 2023.

(30) Foreign Application Priority Data
Jul. 21, 2022 (JP) 2022-116641
Jun. 1, 2023 (JP) 2023-091172

(51) Int. Cl. H01L 21/268; H01L 21/683; H01L 21/78

(52) U.S. Cl. CPC H01L 21/268; H01L 21/6836; H01L 21/78

(57) ABSTRACT

A dicing method of a bonded wafer including a first substrate and a second substrate is used. The first substrate having a first face, and a second face having a recessed portion. A space portion surrounded by the recessed portion and the second substrate, is formed. The method comprising: applying dicing tape to the first face; irradiating the bonding wafer by laser in a stacking direction so as to form a modified region along a dicing line, the dicing line being set on the first substrate so as to be included in a region corresponding to the space portion; dividing the bonded wafer and manufacturing a plurality of singular pieces, with the region corresponding to the space portion of the first substrate still held by the dicing tape, by expanding the dicing tape.

### CROSS-REFERENCE TO RELATED APPLICATIONS

This application is a Continuation of International Patent Application No. PCT/JP2023/021053, filed Jun. 6, 2023, which claims the benefit of Japanese Patent Application No. 2022-116641, filed Jul. 21, 2022, and, Japanese Patent Application No. 2023-091172, filed Jun. 1, 2023, which are hereby incorporated by reference herein in their entirety.

### BACKGROUND OF THE INVENTION

### Field of the Invention

The present invention relates to a dicing method and a recording element manufacturing method.

### Background Art

In manufacturing of wafers, a wafer on which a plurality of semiconductor

elements are arrayed may be diced so as to perform singulation of the semiconductor elements. Wafers can be reinforced against thinness and electrical wiring can be formed by bonding wafers one to another. There are cases with such bonded wafers in which it is necessary to expose a wafer lower layer at the time of dicing for singulation of the semiconductor elements. An example is a case of exposing terminals at the wafer lower layer for external electrical connection.

Japanese Patent Application Publication No. 2016-186526 proposes a dicing method for bonded wafers. In Japanese Patent Application Publication No. 2016-186526, in a bonded wafer, in which a lower layer wafer and an upper layer wafer are bonded, and a hollow portion is provided between the lower layer wafer and the upper layer wafer, terminals are provided on the lower layer wafer at positions facing the hollow portion. Cutting the upper layer wafer with a blade exposes the terminals in the elements obtained from the bonded wafer by singulation.

The method described in Japanese Patent Application Publication No. 2016-186526 cuts the wafer upper layer with a blade, and accordingly there is concern of waste material such as waste cuttings and the like falling, thereby soiling or damaging the wafer lower layer where the terminals are provided.

The present invention has been made in light of the above problem, and an object thereof is to provide technology that suppresses soiling and damage of a wafer when dicing a bonded wafer for singulation of semiconductor elements.

### CITATION LIST

### Patent Literature

PTL1: Japanese Patent Application Publication No. 2016-186526

### SUMMARY OF THE INVENTION

The present invention employs the following configuration. That is, this is a dicing method of a bonded wafer in which a first substrate and a second substrate are stacked and bonded in a stacking direction,
the first substrate having a first face, and a second face in which a recessed portion is formed,
a space portion surrounded by the recessed portion of the first substrate, and the second substrate, being formed by the second face of the first substrate facing the second substrate in the bonded wafer,
the dicing method comprising:
applying dicing tape to the first face of the first substrate;
irradiating the bonding wafer by laser in the stacking direction so as to form a modified region along a dicing line, the dicing line being set on the first substrate so as to be included in a region corresponding to the space portion;
dividing the bonded wafer and manufacturing a plurality of singular pieces, with the region corresponding to the space portion of the first substrate still held by the dicing tape, by expanding the dicing tape.

The present invention also employs the following configuration. That is, this is a recording element manufacturing method of manufacturing a recording element by dicing of a bonded wafer in which a first substrate and a second substrate are stacked and bonded in a stacking direction,
the first substrate having a first face, and a second face in which a recessed portion is formed,
a space portion surrounded by the recessed portion of the first substrate, and the second substrate, being formed by the second face of the first substrate facing the second substrate in the bonded wafer,
a terminal for external electrical connection being provided in a region of the second substrate facing the space portion,
the recording element manufacturing method comprising:
applying dicing tape to the first face of the first substrate;
irradiating the bonding wafer by laser in the stacking direction so as to form a modified region along a dicing line, the dicing line being set on the first substrate so as to be included in a region corresponding to the space portion;
dividing the bonded wafer and manufacturing a plurality of recording elements in which the terminal is exposed, with the region corresponding to the space portion of the first substrate still held by the dicing tape, by expanding the dicing tape.

The present invention also employs the following configuration. That is, this is a dicing method of a bonded wafer in which a first substrate and a second substrate are bonded,
a space portion being formed between the first substrate and the second substrate, and
a terminal for external electrical connection being formed in the space portion,
the dicing method comprising:
applying tape to the first substrate;
irradiating the first substrate by laser at a portion overlapping with the space portion as viewed from a direction that is orthogonal to the first substrate;
irradiating the second substrate by laser at a portion overlapping with the space portion as viewed from a direction that is orthogonal to the first substrate; and
dividing the wafer into a plurality of singular pieces by expanding the tape, with portions irradiated by laser in the irradiating serving as points of origin.

Further features of the present invention will become more apparent from the description of the embodiments, which will be described later with reference to the attached drawings.

### BRIEF DESCRIPTION OF THE DRAWINGS

FIG. 1 is a schematic plan view illustrating a wafer;

FIG. 2A is a schematic perspective view illustrating a wafer structure, and FIG. 2B is a schematic perspective view illustrating a semiconductor element structure that has been obtained by singularization;

FIG. 3 is a flowchart showing a dicing method according to a first embodiment;

FIGS. 4A to 4E are schematic cross-sectional views illustrating wafer severing processes according the first embodiment;

FIG. 5 is a schematic cross-sectional view illustrating a space portion severing method according to the first embodiment;

FIGS. 6A and 6B are schematic cross-sectional views illustrating an expanding step according to the first embodiment;

FIGS. 7A and 7B are schematic cross-sectional views from a different direction, illustrating the expanding step according to the first embodiment;

FIGS. 8A to 8C are schematic cross-sectional views illustrating a semiconductor element sorting step according to the first embodiment;

FIG. 9 is a flowchart showing a dicing method according to a second embodiment;

FIGS. 10A to 10C are schematic diagrams illustrating wafer severing processes according the second embodiment;

FIGS. 11A and 11B are schematic diagrams illustrating a space portion severing method according to the second embodiment;

FIGS. 12A and 12B are schematic views illustrating an example of an inkjet recording element to which the present invention is applied;

FIG. 13 is a schematic diagram illustrating an example of an inkjet recording element unit; and

FIG. 14 is a schematic diagram illustrating an example of an inkjet recording head form.

### DESCRIPTION OF THE EMBODIMENTS

Embodiments of the present invention will be described in detail below with reference to the drawings. It should be noted, however, that dimensions, materials and shapes of components described in the embodiments, relative positions thereof, and so forth, should be changed as appropriate in accordance with configurations of devices to which the invention is applied, various types of conditions, and so forth, and the scope of the invention is not intended to be limited to the following embodiments.

The present invention is suitable for dicing of a bonded wafer in which a plurality of wafers are stacked and bonded. The present invention can be understood to be a dicing method of wafers. Also, the preset invention can be understood to be a recording element manufacturing method, in which elements obtained by dicing (typically, inkjet recording elements used in inkjet recording devices) are manufactured. As an example, in the following embodiments, a bonded wafer having a two-layer structure, in which two wafers are bonded, is divided into a plurality of singular pieces. A space portion is provided at part of a bonded portion of the bonded wafer, and terminals provided on one of the wafers face the space portion. Note, however, that the object of applying the present invention is not limited to this, and the present invention is applicable to bonded wafers in which a greater number of wafers than two layers are bonded, and wafers to which terminals are not provided. Also, an inkjet recording element is exemplified as a semiconductor element, but application may be made to recording elements other than those for the inkjet method, and application may be made to semiconductor elements other than those for recording elements.

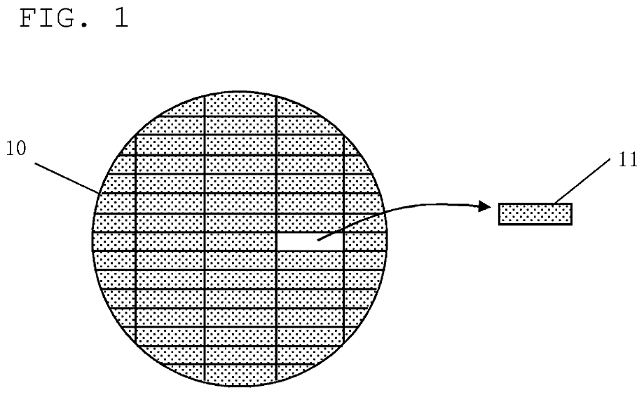

FIG. 1 is a schematic plan view illustrating a wafer to which the present invention is applicable. Severing the wafer 10 into pieces of a predetermined size performs singularization of the wafer 10 into a plurality of singular pieces. The singular pieces manufactured here are semiconductor elements 11.

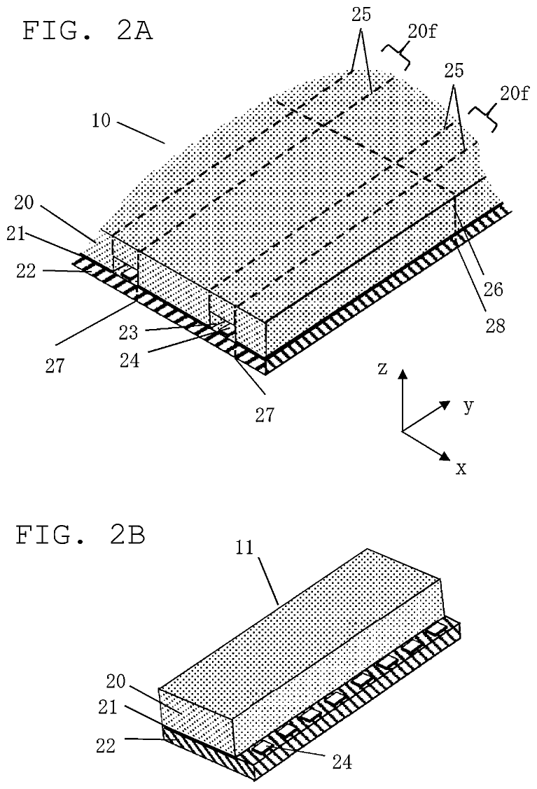

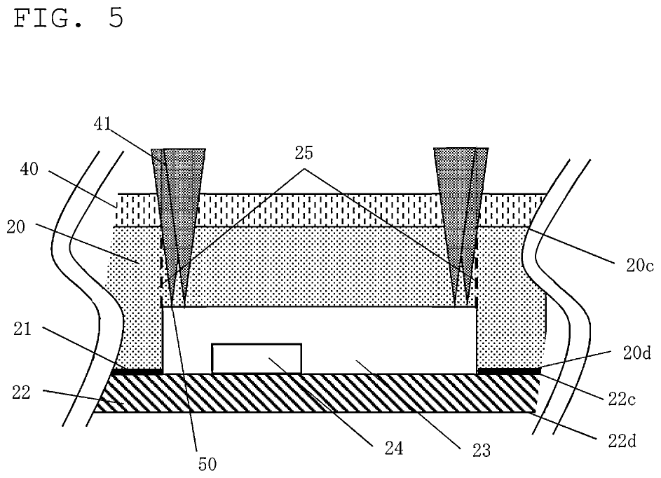

FIG. 2A is a schematic perspective view illustrating a wafer structure to which the present invention is applicable. FIG. 2B is a schematic perspective view illustrating a semiconductor element structure obtained by singularization. As illustrated in FIG. 2A, the wafer 10 is a configuration in which a first substrate 20 and a second substrate 22 are bonded by an adhesive layer 21. Recessed portions are formed on a face side (a second face 20d of the first substrate 20 illustrated in FIG. 5) of the first substrate 20 that is bonded to the second substrate 22. Also, terminals 24 for external electrical connection are provided on a face side of the second substrate 22 (first face 22c of the second substrate 22 illustrated in FIG. 5) that is bonded to the first substrate 20. The first substrate 20 and the second substrate 22 are bonded such that the recessed portions of the first substrate 20 and the terminals 24 of the second substrate 22 overlap. Thus, space portions 23 are formed between the first substrate 20 and the second substrate 22. Note that it is sufficient for the terminals 24 to be formed to face the space portions 23, and accordingly, a configuration may be made in which groove-like recessed portions are provided on an upper face side of the second substrate 22 and the terminals 24 are provided on a bottom face side of the first substrate 20.

Names of the faces of the substrates will be described with reference to FIG. 5. A face of the first substrate 20 to which dicing tape 40 is applied will be referred to as a first face 20c of the first substrate. A face of the first substrate 20 that is on the opposite side from the first face 20c will be referred to as the second face 20d of the first substrate. Also, the face of the second substrate 22 that faces the second face 20d of the first substrate across the adhesive layer 21 will be referred to as the first face 22c of the second substrate. A face of the second substrate 22 that is on the opposite side from the first face 22c will be referred to a second face 22d of the second substrate.

The wafer 10 that has a plurality of layers with a hollow structure configuration such as illustrated in FIG. 2A is severed along dicing lines 25 to 28. The dicing lines 25 to 28 are lines that are set as references for when performing desired dicing of the wafer 10. In dicing, dividing is basically performed along the dicing lines that are set, but there are cases in which actual dividing positions are offset from the dicing lines, which will be described later. As a result, portions of the first substrate 20 that are above the space portions 23 are removed, whereby the terminals 24 on the second substrate 22 that is the wafer lower layer are exposed, and singularization into the semiconductor elements 11 is also performed.

As illustrated in FIG. 2B, the semiconductor element 11 so obtained by singularization from the wafer 10. The semiconductor element 11 according to the present embodiment is an inkjet recording element. External electrical connection of the terminals 24 drives the element, ink is supplied from the first substrate 20, and ink is discharged from the second substrate 22.

As a result of dicing, part of the first substrate 20 (discard-slated portions 20f) become unnecessary at the time of exposing the terminals 24 on the second substrate 22, and become waste material 60. When performing dicing, dicing tape is applied to the first substrate 20 side, whereby the waste material is held by the dicing tape without falling, which will be described later in detail. Accordingly, singularization of the semiconductor elements 11 can be performed with the second substrate 22 and the terminals 24 exposed, while suppressing soiling and damage to the second substrate 22 and the terminals 24. Also, the process is a dry process using stealth dicing, and accordingly soiling of the wafers by cutting fluid can be suppressed.

### First Embodiment

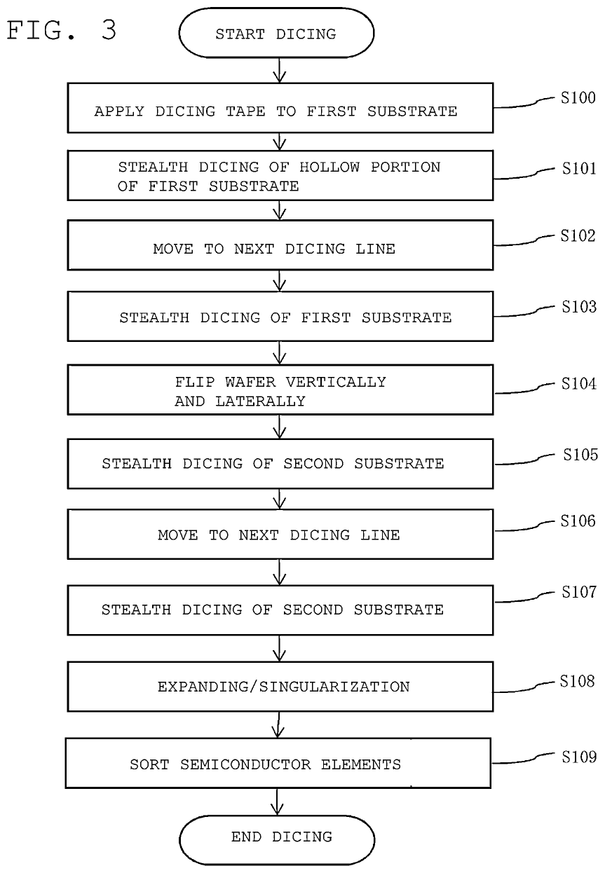

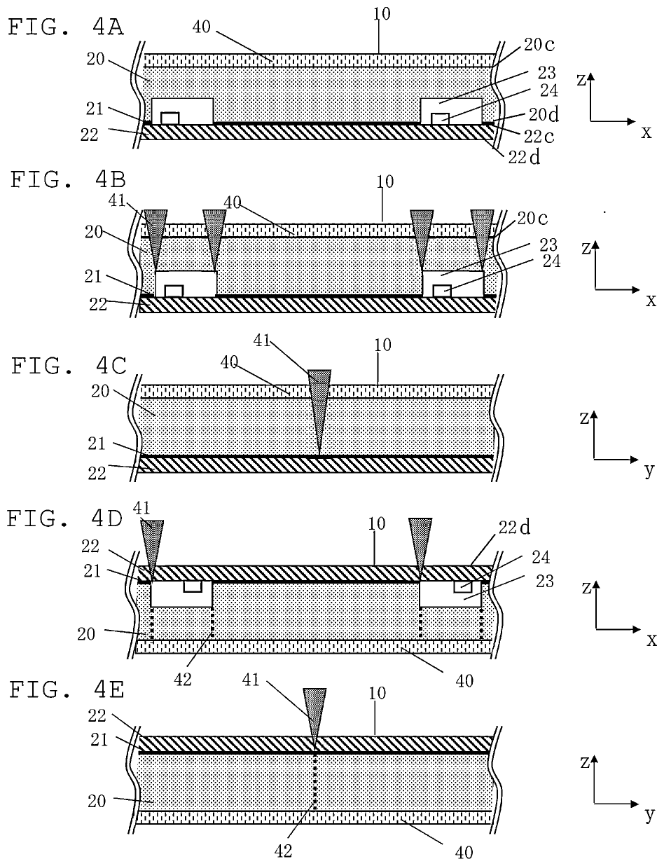

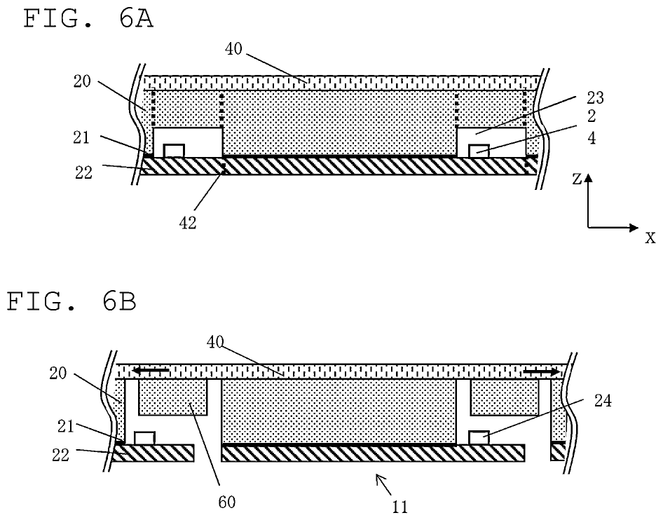

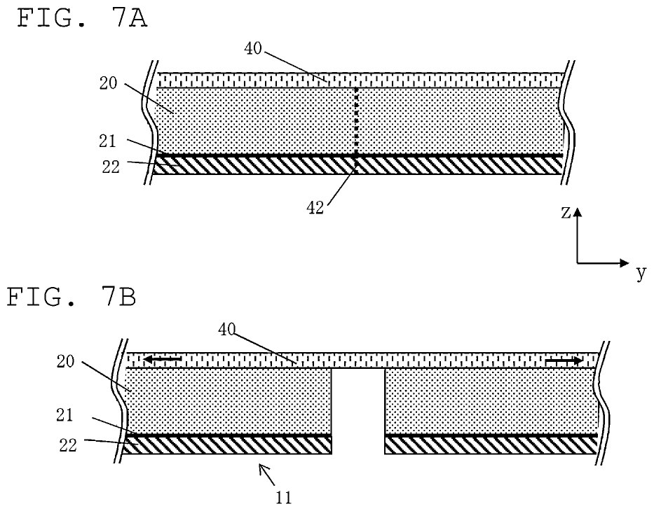

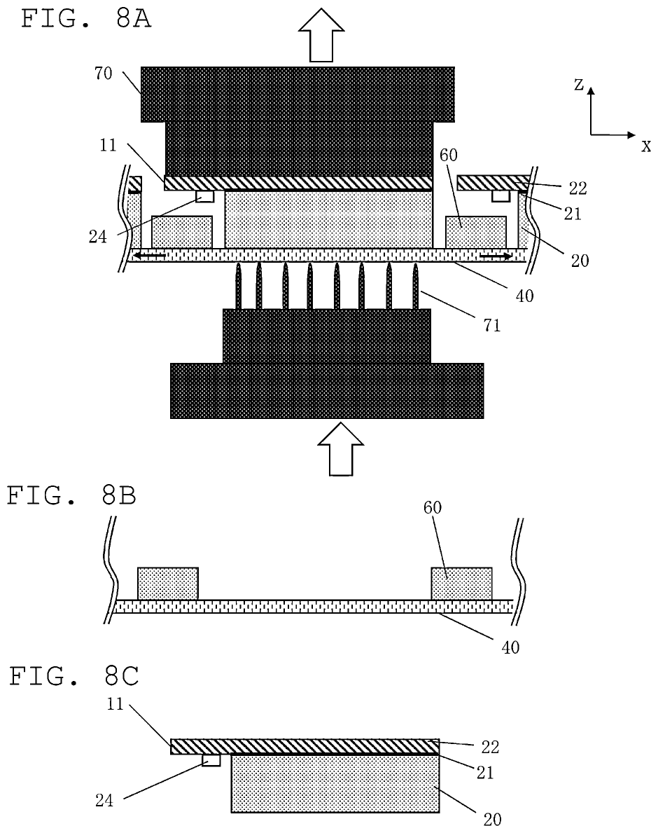

Specific procedures regarding a first embodiment will be described with reference to FIGS. 3 to 8C. FIG. 3 is a flowchart showing a dicing method according to the first embodiment. FIGS. 4A to 4E are schematic cross-sectional views illustrating wafer severing processes according the first embodiment. FIG. 5 is a schematic cross-sectional view illustrating a space portion severing method according to the first embodiment. FIGS. 6A and 6B, and FIGS. 7A and 7B, are schematic cross-sectional views from different directions from each other, illustrating an expanding step according to the first embodiment. FIGS. 8A to 8C are schematic cross-sectional views illustrating a semiconductor element sorting step according to the first embodiment.

First, in step S100, which is an applying step in FIG. 3, the dicing tape 40 is applied to the wafer 10, as illustrated in FIG. 4A. The position for application thereof is on the face of the first substrate 20 that is opposite to the bonding face that is bonded to the second substrate 22 (i.e., the first face 20c of the first substrate 20). The dicing tape 40 is preferably applied and fixed to a general dicing frame (omitted from illustration) that is larger than a wafer outer perimeter, and thereafter applied to the wafer 10. The dicing tape 40 is applied at least to portions corresponding to the space portions 23 in a stacking direction of the first substrate 20 and the second substrate 22. In other words, the dicing tape 40 is applied to portions that become unnecessary at the time of exposing the terminals 24 on the second substrate 22. Note that in a case of using the dicing tape 40 in the expanding step as in the present embodiment, the dicing tape 40 is preferably applied to the entirety of the first substrate 20, as illustrated in FIG. 4A.

A tape that readily transmits laser, which is used in the stealth dicing that will be described later, is preferable for the dicing tape 40. The dicing tape 40 also preferably has sufficient adhesive strength to hold the wafer 10 when dicing. Tape that is capable of weakening the adhesive strength thereof is also preferable, in order to facilitate peeling thereof when sorting the semiconductor elements 11. Examples of conceivable methods of weakening the adhesive strength include curing of adhesive agent by ultraviolet (UV) irradiation, and so forth.

Next, stealth dicing will be described, since severing by stealth dicing will be performed in S101 and thereafter. In stealth dicing, first, laser light is collected by an objective lens optical system, by which the wafer is irradiated along predetermined dicing lines, thereby forming modified regions in which crystal strength in the wafer layer is weakened. Thereafter, the wafer is severed by the expanding step with the modified regions as points of origin, or the like. Due to severing the wafer contactlessly, soiling and damaging of the wafer by waste cuttings and cutting fluid can be suppressed as compared to blade dicing.

Formation of the modified regions will be described in detail. Performing irradiation by laser, such that the laser is collected at a predetermined depth of the wafer, forms the modified regions at the predetermined depth. Now, the wafer is movable in a plane that is perpendicular to a direction of irradiation by the laser. Performing irradiation scanning in which irradiation by the laser is performed at a predetermined cycle while moving the wafer at a predetermined speed enables a layer of modified regions, in which the modified regions are arrayed, to be formed at a predetermined depth of the wafer. Further, performing irradiation scanning by the laser at a plurality of depths with different focal distances enables a plurality of layers of modified regions to be formed in the wafer. Note that the greater the number of layers of modified regions is, the more times the irradiation scanning has to be performed, but efficiency of expanding and accuracy of severing can be improved. The number of layers of the modified regions is preferably adjusted as appropriate in accordance with various factors, such as thickness of the object of severing, intensity of the laser, and so forth. Note that a configuration may be made in which an emission portion for emitting laser 41 from a laser device moves, instead of moving the wafer.

Returning to FIG. 3, description will be continued. In step S101, which is an irradiation step, severing of the first substrate 20 at the top portion of the space portions 23 is performed along the dicing lines 25. As illustrated in FIG. 4B, irradiation by the laser 41 is performed from the first face 20c side of the first substrate 20, through the dicing tape 40. A plurality of layers of the modified regions are formed along the dicing lines 25 while adjusting irradiation depth, within a range from an interface of the first substrate 20 and the space portions 23, to an interface of the first substrate 20 and the dicing tape 40.

Irradiation positions of the laser 41 will be described in detail with reference to FIG. 5. Preferably, regions on an inner side from the dicing lines 25, i.e., inside of regions corresponding to the space portions 23 in the stacking direction, are irradiated by the laser 41. In other words, portions of the first substrate 20 overlapping the space portions 23 as viewed from a direction orthogonal to the first substrate 20 are irradiated by the laser 41. As a result, the irradiation positions of the first substrate 20 by the laser 41 are included in regions in which the space portions 23 are projected in the stacking direction. The reason why this is performed is that in a case of portions outside of the regions of the space portions 23 being irradiated by the laser 41, the first substrate 20 at the top portion of the space portions 23 cannot be severed, and the terminals 24 on the second substrate 22 cannot be exposed. Accordingly, irradiation by the laser 41 is performed such that a laser light collection portion 50 comes within regions corresponding to the space portions 23 in a sure manner, taking into consideration tolerance of the device.

Accordingly, the term “dicing lines” in the present embodiment does not necessarily match actual division lines in some cases, with respect to severing at least the first substrate. That is to say, the actual dividing lines are closer to the space portions 23 than the dicing lines in some cases. Note that the space portions 23 can be exposed even in cases in which portions directly above the dicing lines 25 are irradiated by the laser 41. However, when taking into consideration error in irradiation positions, and a problem regarding light collection which will be described in a second embodiment that will be described later, irradiation of positions facing the space portions 23 as in the present embodiment is preferable.

Note that after being emitted from an emission unit with a predetermined emission width, the laser gradually becomes narrower in width while advancing in the stacking direction of the wafer (z-direction in the drawings), and is collected at a focal point. At this time, the term “irradiation position” can mean directly above the focal point in the stacking direction. Alternatively, the term “irradiation position” may mean a center-of-gravity position of an irradiation region of the first substrate 20 that is irradiated by the laser.

Note that irradiation by the laser 41 within regions corresponding to the space portions 23, instead of directly above the dicing lines 25, results in the first substrate 20 protruding and forming stepped portions in the regions of the space portions 23 in the semiconductor elements 11 following singularization. Accordingly, irradiation by the laser 41 is performed such that the stepped portions are within a tolerance range of the product. Also, in order to sever the first substrate 20 at the top portion of the space portions 23 in a sure manner, increasing the modified regions by performing irradiation of the vicinities of the dicing lines 25 by the laser 41 multiple times, while changing the irradiation position, as illustrated in FIG. 5, is effective.

Returning to FIG. 3, description will be continued. In step S102, the wafer 10 moves to the next dicing line. In the present embodiment, the wafer 10 is rotated by 90° in the same plane. Then in step S103, severing of the first substrate 20 is performed along the dicing lines 26 of the first substrate 20. As illustrated in FIG. 4C, irradiation by the laser 41 is performed from the first substrate 20 side, through the dicing tape 40. A plurality of layers of modified regions are formed along the dicing lines 26 while adjusting the irradiation depth, within a range from an interface of the first substrate 20 and the second substrate 22, to an interface of the first substrate 20 and the dicing tape 40.

In step S104, the wafer 10 is flipped vertically and laterally. Then in step S105, severing of the second substrate 22 is performed along the dicing lines 27 of the second substrate 22. At this time, as illustrated in FIG. 4D, irradiation by the laser 41 is performed from the second face 22d side of the second substrate 22. A plurality of layers of the modified regions are formed along the dicing lines 27 while adjusting the irradiation depth within the second substrate 22. Note that modified regions 42 are formed in the first substrate 20 regarding which irradiation by the laser 41 has already ended. At this time, portions of the second substrate 22 that overlap with the space portions 23 are irradiated by the laser 41, as viewed from a direction orthogonal to the first substrate 20 (i.e., a direction orthogonal to the second substrate 22 as well).

In step S106, the wafer 10 moves to the next dicing line. In the present embodiment, the wafer is rotated by 90° in the same plane. Then in step S107, severing of the second substrate 22 is performed along the dicing lines 28 of the second substrate 22. As illustrated in FIG. 4E, irradiation by the laser 41 is performed from the second substrate 22 side. A plurality of layers of the modified regions are formed along the dicing lines 28 while adjusting the irradiation depth, within the second substrate 22.

In step S108, which is a dividing step, dividing and singularization of the wafer 10 are performed by expanding (expansion). At this time, the dicing tape 40 is expanded from a state such as illustrated in FIGS. 6A and 7A by a predetermined force, and the wafer 10 is divided with the modified regions 42 as points of origin, thereby performing singularization thereof into the semiconductor elements 11, as illustrated in FIGS. 6B and 7B. At the same time, the terminals 24 of the second substrate 22 are also exposed. Meanwhile, the waste material 60 (equivalent to the discard-slated portions 20f of the first substrate 20) that becomes unnecessary at the time of exposing the terminals 24 of the second substrate 22 is held by the dicing tape 40, and does not fall. Accordingly, the second substrate 22 and the terminals 24 can be exposed and singularization of the semiconductor elements 11 can be performed, while suppressing soiling and damage of the second substrate 22 and the terminals 24.

In step S109, the semiconductor elements 11 regarding which singularization has been performed are sorted. As illustrated in FIG. 8A, the semiconductor element 11 are suctioned by a suction collet 70, and at the same time the semiconductor elements 11 are prodded upward by needles 71 on a side thereof that is opposite to the side being suctioned, thereby peeling the semiconductor elements 11 away from the dicing tape 40, one at a time. Before peeling, the adhesive strength is preferably weakened such that the peeling is readily performed. Methods of weakening the adhesive strength include curing of the adhesive agent by irradiating the dicing tape 40 with UV, and so forth. The semiconductor elements 11 that are extracted are sorted into a predetermined tray. Thus, the semiconductor elements 11 such as illustrated in FIG. 8C are obtained by performing singularization. After all semiconductor elements 11 are extracted, all that remains on the dicing tape 40 is the waste material 60, as illustrated in FIG. 8B. The dicing tape 40 and the waste material 60 are discarded. Note that the severing order of steps S101, S103, S105, and S107 in FIG. 3 is not limited in particular, and it is sufficient as long as severing of all dicing lines 25 to 28 can be performed. Also, the order of rotating and flipping the wafer in steps S102, S104, and S106 can be changed as appropriate in accordance with the order of the dicing lines to be severed. Also, when performing laser irradiation from above and below, such as in a case in which three or more layers of wafers are stacked or the like, a boundary of laser from above and below is preferably handled as appropriate, giving consideration to effects of attenuation of the laser.

According to the present embodiment described above, the wafer lower layer can be exposed and singularization of the semiconductor elements can be performed at the time of dicing the bonded wafer, while suppressing soiling and damage of the wafer lower layer.

### Second Embodiment

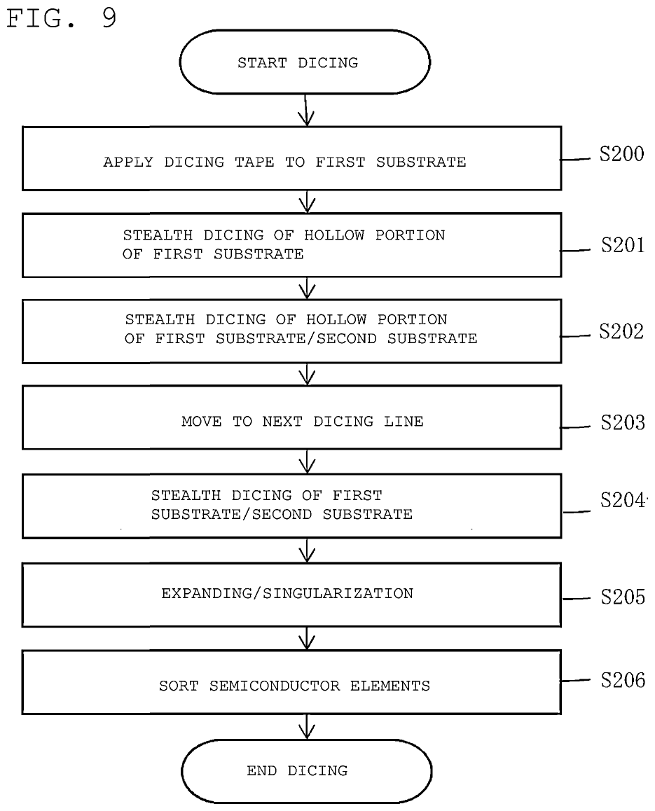

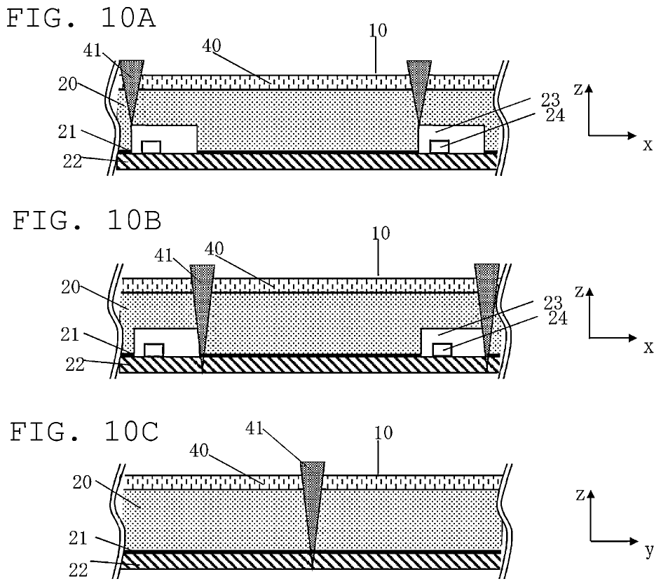

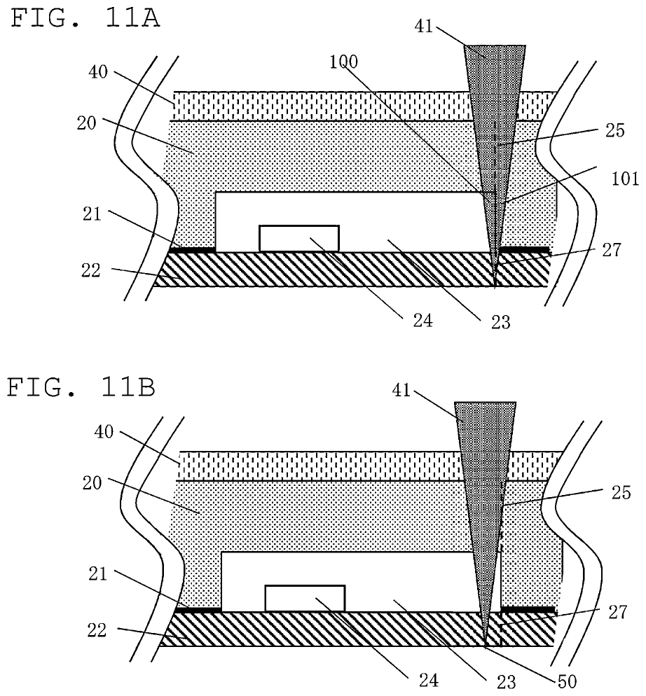

Specific procedures of the second embodiment will be described with reference to FIGS. 9 to 11B. Note that description of portions that are the same as those in the first embodiment will be simplified. FIG. 9 is a flowchart illustrating a dicing method according to the second embodiment. FIGS. 10A to 10C are schematic diagrams illustrating wafer severing processes according to the second embodiment. FIGS. 11A and 11B are schematic diagrams illustrating a space portion severing method according to the second embodiment.

Stealth dicing is used with the present embodiment as well, the same as with the first embodiment. In the first embodiment, irradiation by the laser 41 is performed from above and below the first substrate 20 and the second substrate 22, but in the present embodiment, irradiation is performed from one direction. Irradiation by the laser 41 is performed via the adhesive layer 21 and the space portions 23, and accordingly there is a possibility that severing performance will deteriorate due to laser attenuation as compared to the first embodiment. Conversely, there is no need to vertically flip the wafer 10, which is advantageous with regard to the point that takt time can be shortened. The method according to the present embodiment, and the method according to the first embodiment are preferably used separately in accordance with capabilities of the stealth dicing apparatus, configuration of the wafer 10 desired takt time, and so forth. For example, the present embodiment is advantageous in cases in which output of the laser device is high, and desired working can be achieved even under the effects of attenuation, cases in which a material with small attenuation effects is being used for the adhesive layer 21 of the wafer 10, and so forth.

In step S200 of FIG. 9, the dicing tape 40 is applied to the wafer 10 in the same way as in the first embodiment. In step S201, severing of the first substrate 20 at the top portion of the space portions 23 is performed as illustrated in FIG. 10A, along the dicing lines 25 of the first substrate 20 in the same way as in the first embodiment.

In step S202, severing of the first substrate 20 and the second substrate 22 is performed as illustrated in FIG. 10B, along the dicing lines 25 of the first substrate 20 and the dicing lines 27 of the second substrate 22. A plurality of layers of modified regions are formed along the dicing lines 25 and 27 while adjusting the irradiation depth, within a range from a bottom face of the second substrate 22 to the interface of the first substrate 20 and the dicing tape 40.

Note that in a case of the laser 41 passing through the adhesive layer 21, such as when forming the modified regions in the second substrate 22 in FIG. 10B, the adhesive layer 21 will conceivably cause attenuation of the laser. Accordingly, there is need to correct the effects of attenuation by a method such as increasing laser output, or the like. Attenuation that is assumed to occur is due to absorption by the material itself, and effects of Fresnel reflection at interfaces at which materials with different refractive indices are bonded.

Irradiation positions of the laser 41 will be described in detail with reference to FIGS. 11A and 11B. Now, a straight line that is defined by one dicing line 25 and one dicing line 27 will be considered. This straight line is situated at a vertical-direction boundary of the first substrate 20 and one space portion 23, and on an extended line therefrom. In a case in which the dicing line 25 is irradiated by the laser 41 from directly above, as illustrated in FIG. 11A, the laser 41 is divided into two portions across this boundary line. That is to say, these are a laser first portion 100 (left side in drawing) passing through the space portion 23 in the process of collecting light, and a laser second portion 101 (right side in drawing) passing through the first substrate 20 in the process of collecting light.

It is conceivable that the laser 41 that has passed through different substances at the laser first portion 100 and the laser second portion 101 in this way, will not be correctly collected, and severing performance will deteriorate. Accordingly, the irradiation position of the laser 41 is adjusted such that collection thereof does not occur passing through different substances on the right and left sides. That is to say, the irradiation position of the laser 41 is set to be a position where the laser 41 does not pass through different substances on the right and left sides, such as illustrated in FIG. 11B. To this end, the irradiation position of the laser is set to be within the region of the top portion of the space portion 23. Specifically, in a case of irradiation by the laser 41 from the first substrate 20 side, the point at which the laser light collection portion 50 is on a lower face of the second substrate 22 is a point at which the laser is spread widest within the wafer, and accordingly the laser 41 is set to be contained within the space portion 23 even at this point. Also, severing within the region corresponding to the space portions 23 results in the first substrate 20 partially protruding and forming a stepped portion in the region of the space portion 23 following singularization, in the same way as with the first embodiment. Accordingly, an irradiation position is set such that the stepped portion is within a tolerance range of the product.

In step S203, the wafer 10 moves to the next dicing line. In the present embodiment, the wafer is rotated by 90° in the same plane. Then in step S204, severing of the first substrate 20 and the second substrate 22 is performed along the dicing lines 26 of the first substrate 20 and the dicing lines 28 of the second substrate 22, as illustrated in FIG. 10C. In this case as well, laser attenuation due to the adhesive layer 21 will conceivably occur, in the same way as in step S202. Accordingly, there is need to perform correction in accordance with the effects of attenuation, such as increasing the laser output when the modified region is to be formed through the adhesive layer 21.

In step S205, division and singularization of the wafer 10 are performed by expanding, in the same way as in the first embodiment. According to the present embodiment, performing dicing using the dicing tape 40 enables the second substrate 22 and the terminals 24 to be exposed and singularization of the semiconductor elements 11 to be performed, while suppressing soiling and damage of the second substrate 22 and the terminals 24, in the same way as in the first embodiment.

In step S206, the semiconductor elements 11 obtained by singularization are sorted, in the same way as in the first embodiment. After sorting, all that remains on the dicing tape 40 is the waste material 60, and the dicing tape 40 and the waste material 60 are discarded.

Note that in the present embodiment, irradiation by the laser 41 may be performed from either side of the first substrate 20 and the second substrate 22. That is to say, it is sufficient for irradiation by the laser 41 to be performed from one of the first substrate 20 and the second substrate 22. However, in a case of irradiation from the second substrate 22 side, effects of laser attenuation due to the laser passing through the space portions 23 are received when severing the first substrate 20 at the top portion of the space portions 23, in the same way as in FIG. 10B, unlike as in FIG. 10A. Accordingly, irradiation by the laser 41 is preferably performed from the first substrate 20 side as in the present embodiment, in order to minimize severing portions affected by laser attenuation.

According to the present embodiment described above, in addition to advantages the same as those of the first embodiment, there is an advantageous point in that irradiation by the laser 41 is performed through the adhesive layer 21 and the space portions 23, and accordingly, there is no need to vertically flip the wafer 10, and takt time can be shortened.

### APPLICATION EXAMPLES

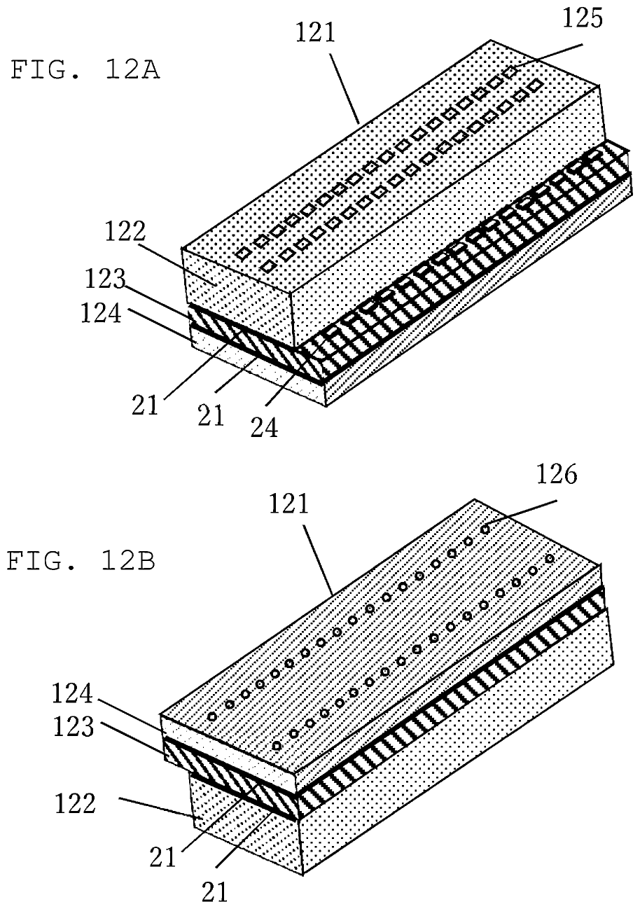

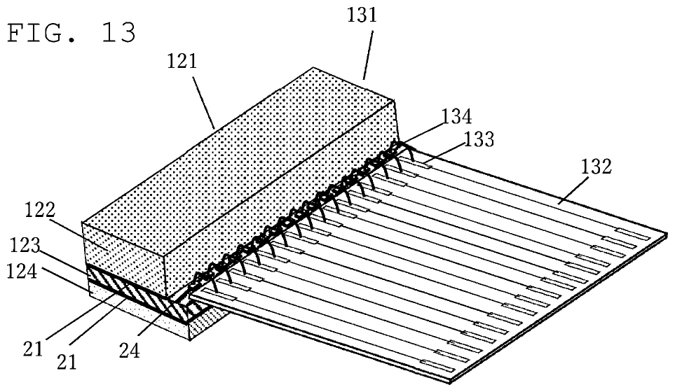

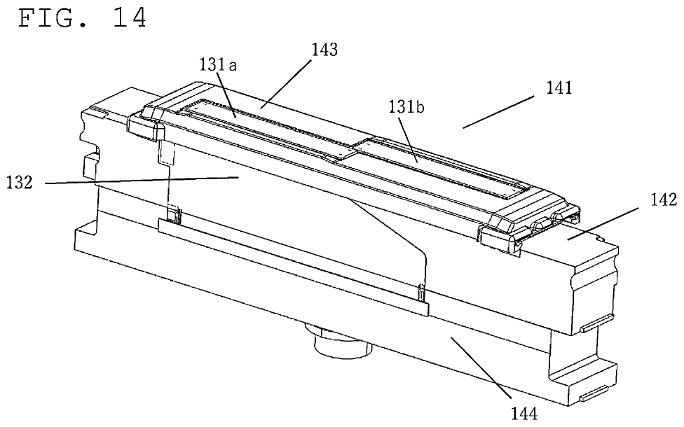

The dicing method according to the first and second embodiments is applicable as a manufacturing method of an inkjet recording head. An application example thereof will be described. FIGS. 12A and 12B are schematic views illustrating an example of an inkjet recording element obtained by the dicing method according to the first and second embodiments. FIG. 12A is a schematic view in which an ink supply orifice side is the upper face, and FIG. 12B is a schematic view in which an ink discharge orifice side is the upper face. FIG. 13 is a schematic diagram illustrating an example of an inkjet recording element unit in which the inkjet recording element in FIGS. 12A and 12B, and an electric wiring board, are electrically connected. FIG. 14 is a schematic diagram illustrating an example in which the inkjet recording element unit in FIG. 13 is in a form of an inkjet recording head.

The inkjet recording element 121 in FIGS. 12A and 12B has a three-layer structure in which an ink channel board 122, an ink discharge energy generating board 123, and an ink discharge board 124 are bonded by adhesive layers 21. The first substrate 20 according to the first and second embodiments corresponds to the ink channel board 122. Also, the portion corresponding to the second substrate 22 is a two-layer structure, to which the ink discharge energy generating board 123 and the ink discharge board 124 correspond.

A plurality of ink discharge orifices 126 for discharging ink are provided to the ink discharge board 124. Also, ink channels 125 for guiding ink to the plurality of ink discharge orifices 126 are formed in the ink channel board 122. Energy generating elements (omitted from illustration) that generate energy for discharging ink from the ink discharge orifices 126 are provided in the ink discharge energy generating board 123. Also, the terminals 24, serving as electric connecting portions for external electric connection, are provided in order to supply electric power to the energy generating elements. Above the terminals 24 is the portion that is the space portion 23 in the form of the wafer 10 before dicing. The inkjet recording element 121 having the space portion 23 with such a three-layer structure is obtained by the dicing method according to the first and second embodiments.

The inkjet recording element unit 131 in FIG. 13 is the inkjet recording element 121 in FIGS. 12A and 12B and an electric wiring board 132 connected to each other. The terminals 24 of the inkjet recording element 121 and lead portions 133 of the electric wiring board 132 are electrically connected in a one-on-one manner, by electrical connecting members 134, using wire bonding. The electrical connecting members 134 will suffice as long as the primary component thereof is, for example, one of metals of gold, copper, aluminum, and silver, or an alloy containing two or more of these metals. Also, the electrical connecting method is not limited to wire bonding, and may be bump bonding, lead terminals, non-conducting paste (NCP), or anisotropic conductive film (ACF). Also, the electric wiring board 132 is, for example, a flexible printed circuit (FPC) or tape-automated bonding (TAB), that supplies electric power to the energy generating elements and exchanges signals with the energy generating elements, in order to discharge ink. The electrical connection portions are commonly protected by a sealant (omitted from illustration).

The inkjet recording head 141 illustrated in FIG. 14 is made up of a supporting member 142 that bonds the inkjet recording element unit 131 in FIG. 13, a face cover 143 that protects the inkjet recording element unit 131, and a channel member 144 that supplies ink. Two units of the inkjet recording element unit 131 (131a, 131b) are arrayed, and the ink discharge orifices 126 are on the upper side in the drawing. Ink is supplied to the inkjet recording element units 131 via the channel member 144 and the supporting member 142, and electrical signals are applied to the electric wiring board 132, thereby enabling discharge of ink.

Although the present invention is described referencing these exemplary embodiments, it should be understood that the present invention is not limited to the exemplary embodiments that are disclosed. The scope of the Claims described later should be given the broadest interpretation, so as to encompass all modifications and equivalent structures and functions.

According to the present invention, technology can be provided that suppresses soiling and damage of the wafer when dicing the bonded wafer for singulation of semiconductor elements.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A dicing method of a bonded wafer in which a first substrate and a second substrate are stacked and bonded in a stacking direction,
the first substrate having a first face, and a second face in which a recessed portion is formed,
a space portion surrounded by the recessed portion of the first substrate, and the second substrate, being formed by the second face of the first substrate facing the second substrate in the bonded wafer,
the dicing method comprising:
applying dicing tape to the first face of the first substrate;
irradiating the bonding wafer by laser in the stacking direction so as to form a modified region along a dicing line, the dicing line being set on the first substrate so as to be included in a region corresponding to the space portion;
dividing the bonded wafer and manufacturing a plurality of singular pieces, with the region corresponding to the space portion of the first substrate still held by the dicing tape, by expanding the dicing tape.

2. The dicing method according to claim 1, wherein a plurality of the singular pieces with a region of the second substrate that faces the space portion being exposed are manufactured by the dividing.

3. The dicing method according to claim 2, wherein a terminal for external electrical connection is provided in the region of the second substrate that faces the space portion.

4. The dicing method according to claim 1, wherein, in the irradiating, the dicing line set on the first substrate is set along a boundary of the singular pieces formed in the dividing, and discard-slated portions not included in the singular pieces.

5. The dicing method according to claim 1, wherein, in the irradiating, an irradiation position on the first substrate by the laser is included in a region in which the space portion is projected in the stacking direction.

6. The dicing method according to claim 5, wherein, in the irradiating, irradiation is performed a plurality of times while changing the irradiation position on the first substrate by the laser.

7. The dicing method according to claim 1, wherein, in the irradiating, irradiation is performed by the laser from the side of the first substrate when forming the modified region on the first substrate, and irradiation is performed by the laser from the side of the second substrate when forming the modified region on the second substrate.

8. The dicing method according to claim 1, wherein, in the irradiating, irradiation is performed by the laser from one or the other side of the first substrate and the second substrate.

9. A recording element manufacturing method of manufacturing a recording element by dicing of a bonded wafer in which a first substrate and a second substrate are stacked and bonded in a stacking direction,
the first substrate having a first face, and a second face in which a recessed portion is formed,
a space portion surrounded by the recessed portion of the first substrate, and the second substrate, being formed by the second face of the first substrate facing the second substrate in the bonded wafer,
a terminal for external electrical connection being provided in a region of the second substrate facing the space portion,
the recording element manufacturing method comprising:
applying dicing tape to the first face of the first substrate;
irradiating the bonding wafer by laser in the stacking direction so as to form a modified region along a dicing line, the dicing line being set on the first substrate so as to be included in a region corresponding to the space portion;
dividing the bonded wafer and manufacturing a plurality of recording elements in which the terminal is exposed, with the region corresponding to the space portion of the first substrate still held by the dicing tape, by expanding the dicing tape.

10. The recording element manufacturing method according to claim 9, wherein a plurality of the singular pieces with a region of the second substrate that faces the space portion being exposed are manufactured by the dividing.

11. The recording element manufacturing method according to claim 9, wherein, in the irradiating, the dicing line set on the first substrate is set along a boundary of the singular pieces formed in the dividing, and discard-slated portions not included in the singular pieces.

12. The recording element manufacturing method according to claim 9, wherein, in the irradiating, an irradiation position on the first substrate by the laser is included in a region in which the space portion is projected in the stacking direction.

13. The recording element manufacturing method according to claim 12, wherein, in the irradiating, irradiation is performed a plurality of times while changing the irradiation position on the first substrate by the laser.

14. The recording element manufacturing method according to claim 9, wherein, in the irradiating, irradiation is performed by the laser from the side of the first substrate when forming the modified region on the first substrate, and irradiation is performed by the laser from the side of the second substrate when forming the modified region on the second substrate.

15. The recording element manufacturing method according to claim 9, wherein, in the irradiating, irradiation is performed by the laser from one or the other side of the first substrate and the second substrate.

16. An inkjet recording head that is equipped with a plurality of inkjet recording elements formed from the bonded wafer by the dicing method according to claim 1.

17. A dicing method of a bonded wafer in which a first substrate and a second substrate are bonded,
a space portion being formed between the first substrate and the second substrate, and
a terminal for external electrical connection being formed in the space portion,
the dicing method comprising:
applying tape to the first substrate;
irradiating the first substrate by laser at a portion overlapping with the space portion as viewed from a direction that is orthogonal to the first substrate;
irradiating the second substrate by laser at a portion overlapping with the space portion as viewed from a direction that is orthogonal to the first substrate; and
dividing the wafer into a plurality of singular pieces by expanding the tape, with portions irradiated by laser in the irradiating serving as points of origin.
